(19) United States
(12) Patent Application Publication
(10) Pub. No.: US 2016/0285310 A1
(43) Pub. Date: Sep. 29, 2016

(54) SMART ELECTRICAL POWER METER WITH AUTO-SWITCHING CONTROL FOR OPTIMIZING ENERGY SAVINGS

(71) Applicants: Liangcai Tan, Dublin, CA (US); Xin Hu, Dublin, CA (US); Michael Wilson, Oakland, CA (US)

(72) Inventors: Liangcai Tan, Dublin, CA (US); Xin Hu, Dublin, CA (US); Michael Wilson, Oakland, CA (US)

(73) Assignee: BRITE THINGS, INC., Dublin, CA (US)

(21) Appl. No.: 15/077,653

(22) Filed: Mar. 22, 2016

Related U.S. Application Data
(60) Provisional application No. 62/136,855, filed on Mar. 23, 2015.

(51) Int. Cl. H02J 13/00; G01R 22/10; G01V 8/10; G01R 22/06

(52) U.S. Cl. CPC H02J 13/0017; G01R 22/068; G01R 22/10; G01V 8/10; H02J 13/001

(57) ABSTRACT

The present invention is a power meter with auto switching control. It comprises a power measurement unit where the power and energy data can be display either locally as well as remotely through wireless communications, an electrical receptacle, plug or strip connecting power to electrically powered equipment or devices; a switch with open and close states to control power off and on; a combination of buttons for manual controls and settings; embedded or externally connected sensors to provide signal input, for example but not limited to, occupancy sensors and infrared sensors; a processing unit to automatically control the power on/off according to the measured power, sensor signals, user input, schedules and control strategies; and storage units to hold these control strategies and algorithms and save data.

### FIELD OF THE INVENTION

The present invention relates to electrical power measurement and control, and more specifically, to electrical power measurement, display and auto-switching control for electrical receptacles, plug and strip equipment with voltage less than 600 V designed to automatically turn on/off plugged in devices in order to save energy and educate consumers about their power usage.

### BACKGROUND OF THE INVENTION

There are many electrical receptacles, plugs and strips, switches, timers, and power meters on the market designed to measure and manage plug loads. However most of these products have only a single function; such as power metering or switching, but typically not both and there are no devices that combine these two features that are able to automatically turn on/off devices based on user preferences and behavior and automatically override settings when user behavior changes, ensuring power is available to the user when needed.

In addition, current electrical receptacles, plugs and strip devices that allow electrically operated equipment to be connected to a power supply, may include switching capability, but generally they do not also include power measurement functions nor sensors to detect user presence or interaction with power control devices to capture user behavior and override settings or automatically modify settings to adapt to changes in device usage and user behavior.

In summary, prior art may include power metering and display and or power switching. However, no previous devices incorporate both power metering and switching with sensors and programming to help users save energy by turning off devices when they don't need them. In addition this device can automatically override presets to adopt to user behavior to ensure when they need to use electrical devices that they are connected to power rather than forcing a user to manually turn on/off devices.

The present invention combines measurement and controls. It uses schedules, manual inputs, sensor inputs, power measurement results, and/or other rule sets to control the power on or off, which in turn can save energy for appliances or equipment connected to it. It is an integrated device with two or more combined functions of power meter, receptacles, plugs, strips, occupancy sensors, infrared sensors, switches and timers.

The present invention can display the measurement and control results either by including a liquid crystal display (LCD) in the device or by displaying results through connected smart phones, pads, computers, web or cloud services, or other means. The device may include a number of buttons for manual switching and/or setting up devices. The device may include occupancy and/or infrared sensors to detect motion and/or signals from any infrared remote controllers, either supplied with the device or from third parties for other purposes, for example, but not limited to, the remote controller for TV, DVD, Audio, play stations, and etc. It may also include a WiFi or other wireless communications component, which can send and receive data to a central controller, server or cloud-based services.

These features make the device smart and easy of use. Users will plug it into a power source, plug their equipment or appliances into the device. The device records power usage, motion presence and develops suggested on/off schedules designed to optimize energy savings. The device continuously detects changes in power draw, occupancy and/or infrared sensors, and follows schedules and control strategies programmed into the device based on manufacturer's default setup, user inputs and/or recommendations from servers sending further optimization suggestions to users via onboard screen or via internet connected devices, computers and/or control systems.

The present invention also provides real time power measurement as well as energy usage information to users, so they will see their connected equipment energy use, for example but not limited to power demand, power characteristics, real time and accumulated energy use and energy cost, and know the amount of energy wasted when the equipment is left on unnecessarily. Values of energy savings are presented in formats and relevant modes per user selection. For example, kilowatt, Kilowatt-hours, Money Saved, CO2 saved and so forth. The awareness of energy use and energy waste is intended to motivate users' behavior change to take actions to save energy. Since the power measurement feature of the present invention continuously records the power usage data, the amount of energy savings can also be calculated, which in turn can be very useful feedback to the users in the means of continuously rewarding good behaviors and encourage additional positive actions.

The devices on/off functions are also able to adapted to many scenarios to save energy as well as enhance security, safety and provide convenience to users. For example, remote on/off control of any plugged in device via mobile to turn on any device or other appliances when user is away from the home or in another part of a house. This device can also be used as a timer to switch power on and off based on the schedule set up by the users, for example lights turn on automatically as a security measure. It can be used to turn off the power when the power usage is lower than the set-point to mitigate wasteful standby power, also known as vampire power. It can also be used to measure power and provide data to users to increase users' awareness of power usage and enable users' controls over their electrical equipment.

Furthermore, the present invention accepts control signals from sensors, including built-in or externally connected sensors, to control the electrical equipment power on and off. The embedded or external sensor can be an occupancy sensor, infrared sensor or any other sensor types, either wired or wireless. For example, the occupancy sensor can be used to control power off when a space is not occupied for more than a pre-set amount of time as dictated by the user or by power usage profiles contain within the device to reduced wasted energy. Another example, of the present inventions ability to accept input from sensors is to receive infrared signals from TV remote controllers, as an indicator of users proximity and to capture user interactions with the plugged in device.

### SUMMARY OF THE INVENTION

In accordance with the present invention, which includes all or some of these listed features and functions, there is provided a smart electrical power meter with auto-switching control for optimizing energy savings. It comprises a power measurement unit that measures power and calculates results and can either display these results locally on an LCD display within the present invention and/or displayed remotely on smart phones, pads, computers, or web-based servers through WiFi or other wireless communication means; an electrical receptacle, plug or strip for connecting power to electric equipment; a switch with open and close states to control power on/off; a number of buttons for user inputs, for example but not limited to, manual on/off switch, power set-point and delay time setting; embedded or externally connected sensors to provide signal input, for example but not limited to, occupancy sensors and infrared sensors; a processing unit to automatically control the power on/off according to the measured power, sensor signals, user input, schedules and control strategies; and storage units to hold these control strategies and algorithms and save data.

It is advantageous to show power and energy savings data on a local LCD display within the present invention and/or smart phones, pads, computers, or web-based servers through WiFi or other wireless means. This information will help users understand how much energy connected devices, are consuming, and help them to make informed decision about energy use, savings and conservation.

It is advantageous to provide an automatic switching control according to the measured power, sensor signals, user input, schedules and control strategies. This will help users to save energy by turning the equipment off when it is not needed, and eliminating standby power, also called vampire power.

It is advantageous to provide a set of buttons for easy setting and manual on/off switching. This helps users to adapt equipment energy usage to different usage scenarios, when WiFi connections are not present, to turn their equipment on/off at any time they desire, and to override the existing programming.

It would further be advantageous to provide a sensor such as an occupancy sensor and/or infrared sensor to turn the power off when the power is on. This helps users save more energy when spaces are not occupied or other conditions are detected. Finally, this invention introduces a level of convenience to users because the use of occupancy and infrared sensors to turn the power on automatically when a user is nearby despite preset schedules that would otherwise have the power turned off, ensure users always have access to their equipment, for example late a night or weekends when they normally would not interact with these equipment.

### BRIEF DESCRIPTION OF THE DRAWINGS

A complete understanding of the present invention may be obtained by reference to the accompanying drawings, when considered in conjunction with the subsequent, detailed description, in which:

FIG. 1 is a perspective view of a smart electrical power meter with auto-switching control for optimizing energy savings (first embodiment);

FIG. 2 is a detail view of a block diagram of the main circuit board;

FIG. 3A is a detail view of a main work flow of the present invention;

FIG. 3B is a detail view of the local learning algorithm of the present invention;

FIG. 4 is a perspective view of a smart electrical power meter with auto-switching control for optimizing energy savings (second embodiment) featuring in-wall installation option via direct wiring connection; and

FIG. 5 is a perspective view of a power meter with auto switching control featuring multiple plug inputs (third embodiment).

For purposes of clarity and brevity, like elements and components will bear the same designations and numbering throughout the Figures.

### DESCRIPTION OF THE PREFERRED EMBODIMENT

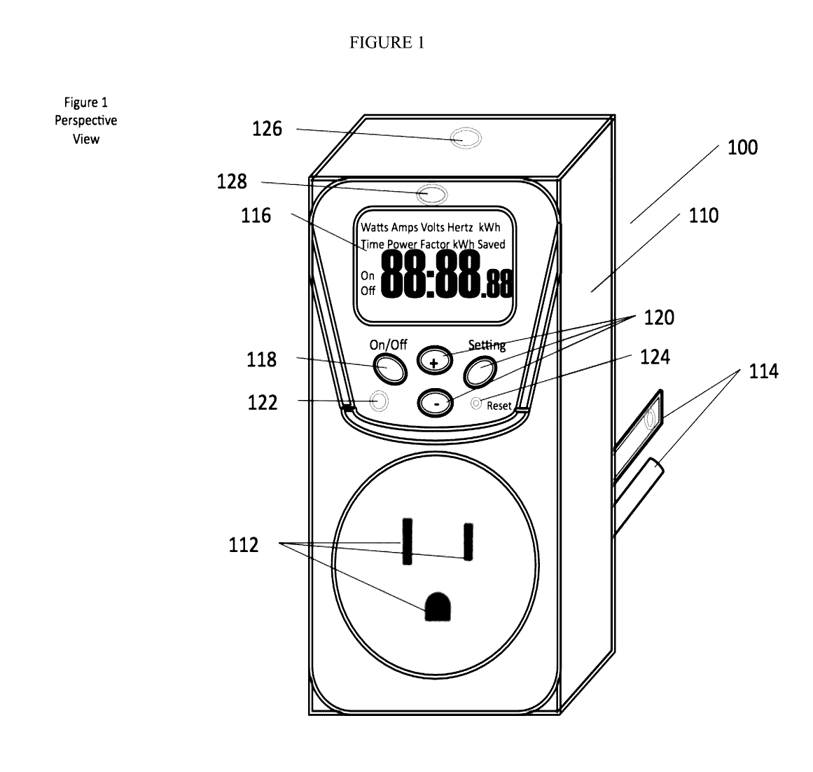

The preferred first embodiment as shown in FIG. 1 is a smart electrical power meter with auto-switching control for optimizing energy savings 100. It consists of a shell 110, a connector to load 112, a connector to power source 114, internal sensors 128, an external sensor signal input 126, a LCD 116, a manual on/off button 118, a set of setting buttons 120, indication lights 122, an optional reset button 124 and the main circuit board 200 inside the shell 110.

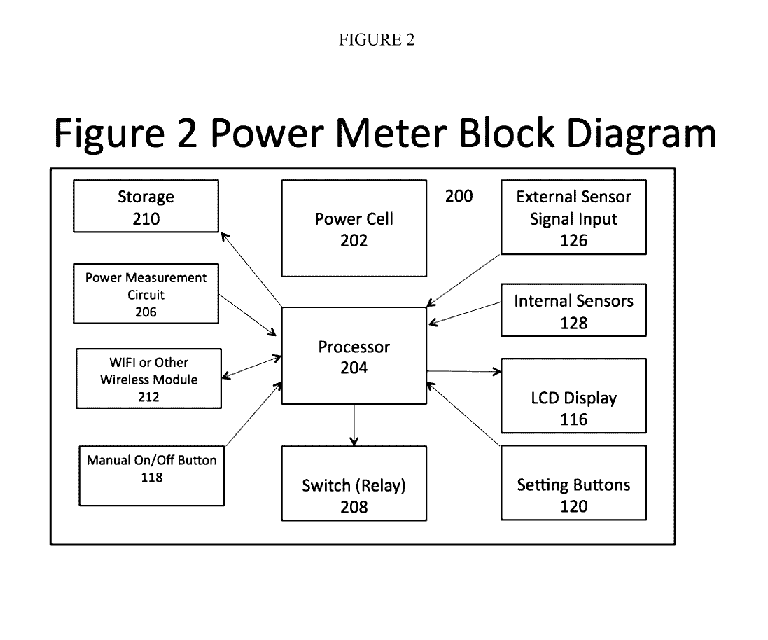

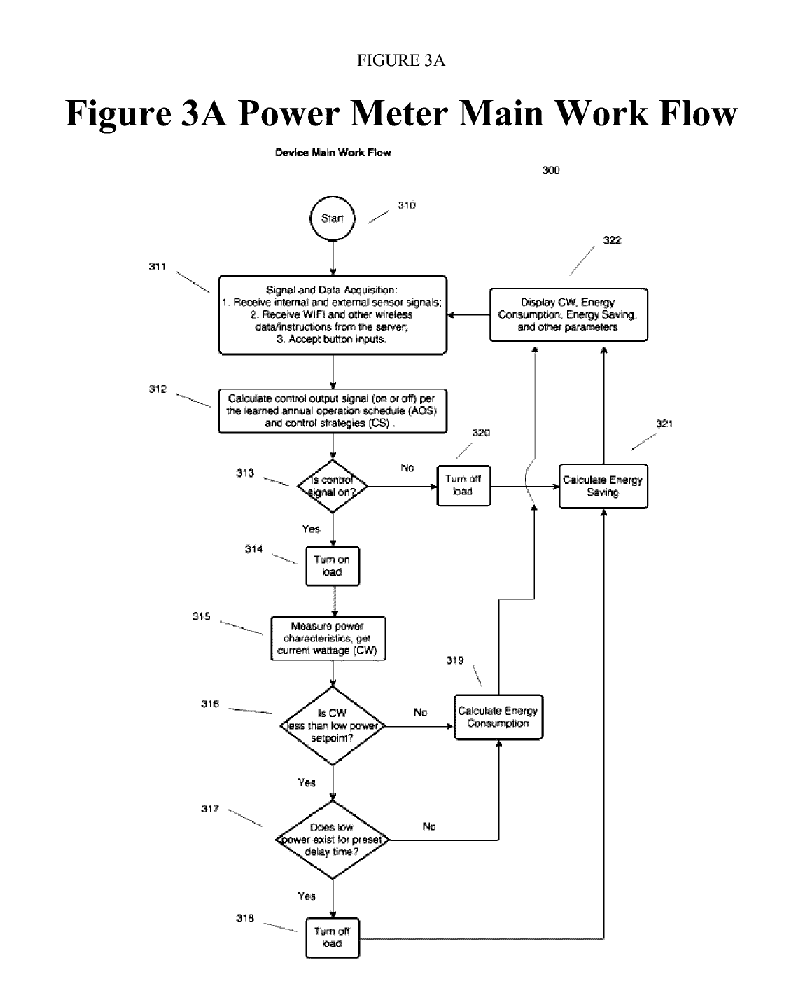

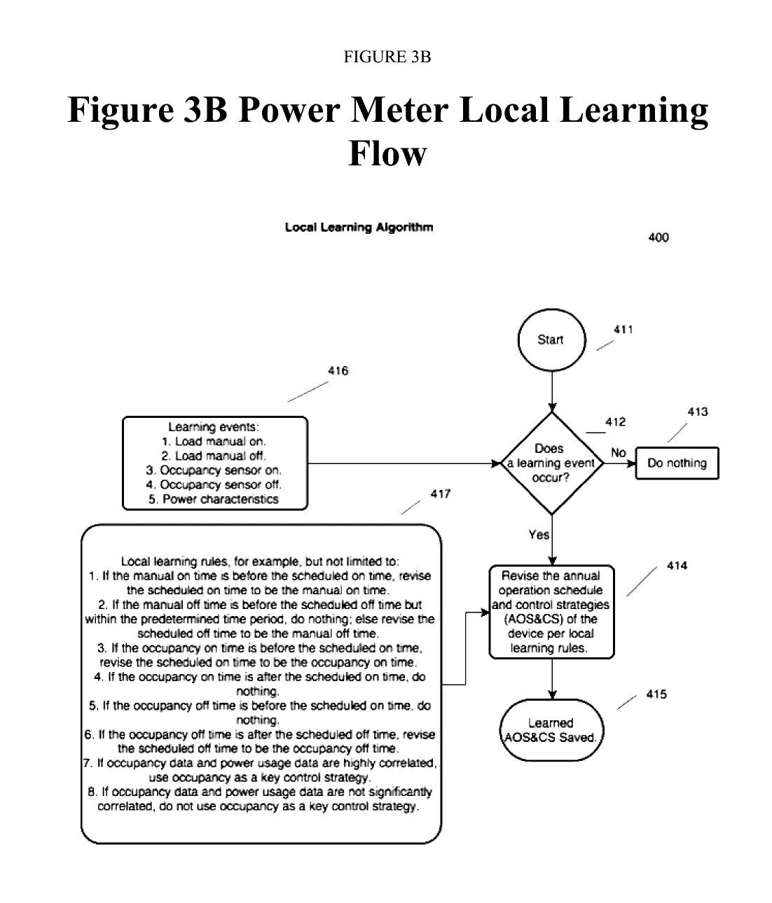

The main circuit board 200 is shown in FIG. 2. The main circuit board 200 consists of a power cell 202, a processor 204, a power measurement circuit 206, a switch (relay) 208, storage 210, and a WiFi or other wireless module 212. The main work flow and sequence of control is shown in FIG. 3A. The device local learning flow is shown in FIG. 3B.

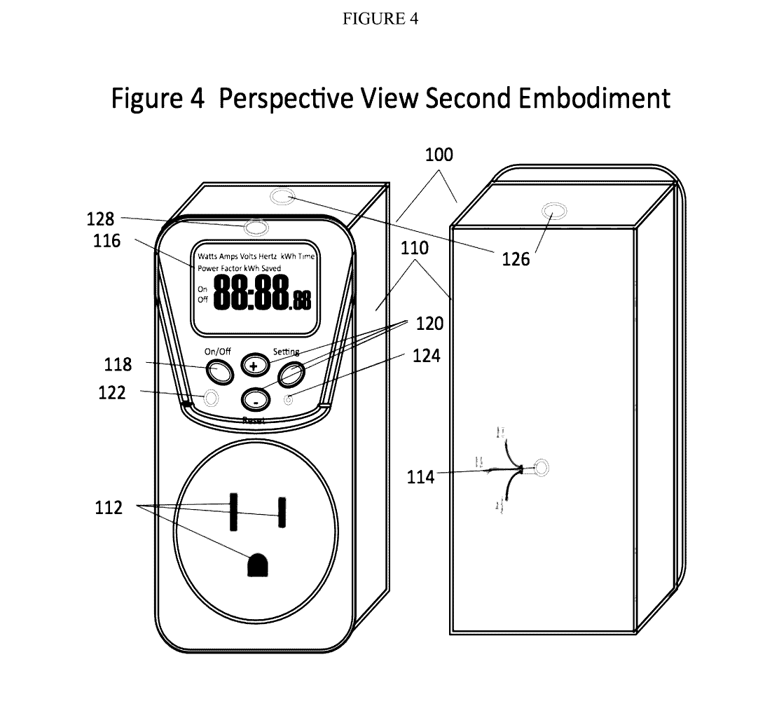

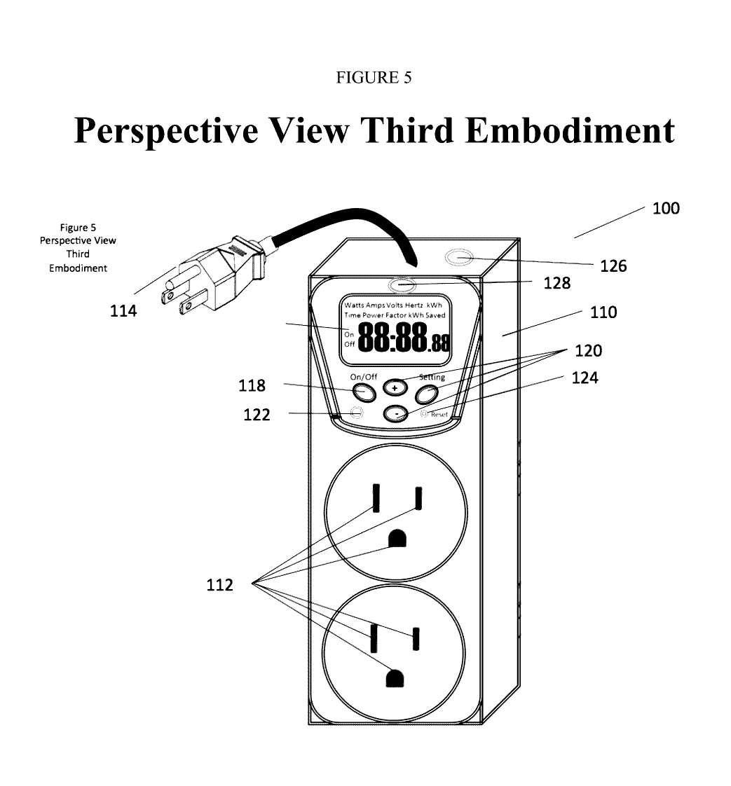

The second embodiment is shown in FIG. 4, which can be installed within a wall. The third embodiment is shown in FIG. 5, which is a strip type. The shell 110 is non-conductive, plastic, for holding all the elements of 100.

The connector to load 112 is a female connector as shown in FIGS. 1, 4 and 5, for connecting the present invention to load side devices like appliances, television (TV), computers and monitors, and other receptacle equipment, tightly connected to said shell 110, but not limited to direct connect and may be individual plug extensions

The connector to power source 114 is a male connector as shown FIG. 1, electrical wires as shown in FIG. 4, or extension cord as shown in FIG. 5, for connecting the electrical power from a power outlet or electrical panel to the present invention, tightly connected to said shell 110.

The number of connectors to load is not limited to one. It can be two or more as shown in FIG. 5 (the third embodiment of the present invention).

The round jack external sensor signal input 126 is for connecting external sensor like motion or infrared via cable to the present invention for automatically controlling the power off, connecting external sensor to main circuit board 200.

The internal sensors 128 are sensors used to control the present invention device on and off. They can be mounted directly to the shell 110 and welded to the main circuit board 200. The internal and external sensors can be occupancy sensor, infrared receiving sensor or any other sensors or devices which can be wired or wireless. For example, the occupancy sensor can be used to control power off when a space is not occupied for more than a pre-set time, such as 30 minutes, to save energy. Any other device such as a external equipment can send signal to the present invention through the external sensor signal input 126 to control the power off when the power is on.

The LCD 116 can be any shape as required by design to fit into or onto said device, for displaying power characteristics and setting parameters.

The manual on/off button 118 is a button, for manually switching the power on or off to cut the power to the load. Location of this button is shown in the upper left side in FIG. 1 but may be located anywhere on the device in future embodiments based on design and user specifications.

The setting buttons 120 are a set of buttons, square or round, labeled clearly for setting the parameters such as low power set-point, delay time and scheduling but not strictly limited to just these setting types. Three buttons are envisioned, one for changing setting mode and the other two for increasing or decreasing the setting values. In some situations, two buttons are envisioned when space on the surface of the device is limited, or four or more buttons to allow separate setting buttons 120 for low power setpoint and delay time respectively, scheduling and other device related control features that might be set manually.

The indication lights 122 are a set of LED lights, for indicating status such as, but not limited to when , power is connected to the load, whether a WiFi or other wireless module 212 is running in configuration mode, normal mode or with errors.

The reset button 124 is small, concave, for restarting the present invention in case it stops running.

The power cell 202 (FIG. 2) is a power adaptor, alternating current (AC) to direct current (DC) convertor, with surge protection feature, for providing DC power to the main circuit board 200;

The main circuit board 200 is a printed circuit board with electronic elements welded to it, for implementing all the display and control functions of the present invention, connected to power cell 202, connected to reset button 124, connected to indication light 122, connected to setting buttons 120, connected to manual on/off button 118, connected to LCD 116, and rigidly connected to shell 110.

The processor 204 is a central process unit, for processing all the requests from other elements, running the main work flow and device local learning algorithm, calculating energy used and energy savings, and sending out control instructions, connected to main circuit board 200. An example of the processor 204 is a low power microcontroller such as Vango Technologies V9011 which is a energy metering SoC chip, featuring low-power dissipation and high-performance.

The power measurement circuit 206 is an electronic module for for measuring power characteristics such as wattage, voltage, amperage, frequency and power factor, connected to main circuit board 200. An example of the power measurement circuit 206 is a single-phase energy metering SoC chip such as Vango Technologies V9011.

The switch (relay) 208 is an electrical relay with open and close states, for switching the power on (open state) and off (close state), connected to main circuit board 200.

The circuit board 200 also includes storage units 210, such as an electrically erasable programmable read-only memory (EEPROM) high-speed random access memory, and/or a non-volatile memory such as a flash memory device. The storage units 210 are used for saving the measured and calculated data, holding the annual operation schedule (AOS) and control strategies (CS), and holding the device main work flow and local learning algorithm as shown in FIGS. 3A and 3B.

The circuit board 200 can also have one or more communication modules, including a WiFi or other wireless module 212. The WiFi or other wireless module 212 can be a module with an antenna for providing data communication through WiFi or other wireless protocol. An example of such a module 212 is AI Thinker ESP8266.

FIG. 3A is a detail view of a main work flow of the present invention. It includes a signal or data input where the process starts 310. The signal is acquired 311, from either external or internal sensors, WiFi or other wireless communication from the server, as well as direct inputs from the device via input buttons located externally on the device. Next, the acquired information is passed to 312 where it is identified as a control output signal (on/off) and compared with the devices current annual operating schedule (AOS) and/or the assigned control strategy. At 313 if the control signal is “On” then “Turn on Load” 314 is activated. If the result of 313 is negative then signal flows to “Turn off load” 320. From this point energy savings are calculated 321 and displayed 322. In cases where the load is “on” 314 then the system measures the power characteristics and gets current wattage (CW). This information is passed to 316 where wattage is compared to a low-point setting. If the CW is NOT less than an existing setting then it is assumed the device is being utilized and the process flows to 319 where current energy consumption is captured and displayed at 322. If the CW is less than a set low point the process moves to 317 where the process checks for a preset delay time. If no delay time is present the process reads the current wattage, calculates energy consumption 319 and displays the result 322. If a low point delay time preset exists then the process will turn off the load 318.

FIG. 3B is a detail view of a local learning algorithm 400. The process envisioned in FIG. 400 describes the local learning flow and method for optimizing device energy efficiency. This process begins at 411, when at step 412 the device must determine if a learning event occurs. If no event is present the system will do nothing 413. If learning events, such as, 1) Load manual on, 2) Load manual off, 3) Occupancy sensor on 4) Occupancy sensor off, occurs, then the process advances to 414, described as a revision of the Annual operation schedule (AOS) as dictated by local learning rules FIG. 417.

Learning rules described in step 417 my include but are not limited to Local learning rules, for example, but not limited to: 1) If the manual on time is before the scheduled on time, revise the scheduled on time to be the manual on time; 2)If the manual off time is before the scheduled off time but within the pre-determined time period, do nothing; else revise the scheduled off time to be the manual off time; 3) If the occupancy on time is before the scheduled on time, revise the scheduled on time to be the occupancy on time; 4)If the occupancy on time is after the scheduled on time, do nothing; 5)If the occupancy off time is before the scheduled on time, do nothing; 6) If the occupancy off time is after the scheduled off time, revise the scheduled off time to be the occupancy off time; 7) If occupancy data and power usage data are highly correlated, use occupancy as a key control strategy; 8) If occupancy data and power usage data are not significantly correlated, do not use occupancy as a key control strategy.

FIG. 5 is a perspective view of a power meter with auto switching control featuring multiple plug inputs (third embodiment). It is envisioned to contain all the same operational features as described above for FIG. 1. FIG. 5 details the concept of multiple load inputs 112, each input 112 behaving in the same manner as described in FIG. 1 so that each device connected via input 112 can be identified and controlled independently from any other device plugged into the unit. FIG. 5 also indicates removal of fixed prongs (FIG. 1 114) and details a secondary power connection methodology utilizing a flexible power cable of any length and power connector 114 to enable the device to receive power in the same manner as described above in FIG. 1.

Other modifications and changes can be varied to fit particular operating requirements and environments will be apparent to those skilled in the art, the invention is not considered limited to the example chosen for purposes of disclosure, and covers all changes and modifications which do not constitute departures from the true spirit and scope of this invention.

Having thus described the invention, what is desired to be protected by Letters Patent is presented in the subsequently appended claims.

What is claimed is:

1. A smart electrical power meter with auto-switching control for optimizing energy savings for measuring electrical power and using the measured data for automatic control, comprising:
a means for measuring power parameters;
a means for displaying power characteristics either by including a liquid crystal display (LCD) in the device or by displaying results through connected smart phones, pads, computers, web or cloud services, or other means;
a means for switching the power on or off to cut the power to the load;
a means for manually setting parameters;
a means for detecting sensor signals for detecting motion or infrared signals;
a means for connecting external sensors for detecting motion or infrared signals;
a means for WiFi or other wireless communication for providing data communication through WiFi or other wireless protocol;
a means for processing information according to the local learning algorithm, making power on/off control decision and executing the set decision;
a means for calculating energy used and energy savings;
a means for storing data, control strategies and algorithms.

2. A smart electrical power meter with auto-switching control for optimizing energy savings in accordance with claim 1, wherein said means for holding all the elements of 100 comprises a non-conductive, shell.

3. A smart electrical power meter with auto-switching control for optimizing energy savings in accordance with claim 1, wherein said means for connecting the present invention to load side comprises one or more female connectors to load.

4. A smart electrical power meter with auto-switching control for optimizing energy savings in accordance with claim 1, wherein said means for connecting the electrical power from power outlet or electrical panel to the present invention comprises a male connector or electrical wires connector to power source.

5. A smart electrical power meter with auto-switching control for optimizing energy savings in accordance with claim 1, wherein said means for indicating whether the power is connected to the load comprises an LED light indication light.

6. A smart electrical power meter with auto-switching control for optimizing energy savings in accordance with claim 1, wherein said means for provide DC power to the main circuit board comprises a power adaptor, AC to DC convertor power cell.

7. A smart electrical power meter with auto-switching control for optimizing energy savings in accordance with claim 1, wherein said means for implementing all display and control functions of the present invention comprises a printed circuit board.

8. A smart electrical power meter with auto-switching control for optimizing energy savings in accordance with claim 1, wherein said means for connecting external sensors to the present invention for automatically controlling the power off, comprises a round jack, cable and sensor unit.

9. A smart electrical power meter with auto-switching control for optimizing energy savings in accordance with claim 1, wherein said means for measuring power characteristics like wattage, voltage, amperage, frequency and power factor comprises an electronic module for power measurement.

10. A smart electrical power meter with auto-switching control for optimizing energy savings in accordance with claim 1, wherein said means for displaying real time power measurement and energy usage information to users.

11. A smart electrical power meter with auto-switching control for optimizing energy savings in accordance with claim 1, wherein said means for setting the parameters, such as but not limited to, scheduling, power level, delay time, and default display.

12. A smart electrical power meter with auto-switching control for optimizing energy savings in accordance with claim 1, wherein said means for manually switching the power on or off to cut the power to the load comprises a manual on/off button.

13. A smart electrical power meter with auto-switching control for optimizing energy savings in accordance with claim 1, wherein said means for switching the power on (open state) and off (close state) comprises an electrical relay, with open and close states switch.

14. A smart electrical power meter with auto-switching control for optimizing energy savings in accordance with claim 1, wherein said means for detecting signals, for example but not limited to occupancy sensors and infrared sensors.

15. A smart electrical power meter with auto-switching control for optimizing energy savings in accordance with claim 1, wherein said means for connecting to external sensors, for example but not limited to occupancy sensors and infrared sensors.

16. A smart electrical power meter with auto-switching control for optimizing energy savings in accordance with claim 1, wherein said means for wireless communication to send and receive data to central controllers, servers, cloud-based services and external devices.

17. A smart electrical power meter with auto-switching control for optimizing energy savings in accordance with claim 1, wherein said means for processing requests from other elements, calculating energy used and energy savings, and sending out control instructions comprises a central process unit processor.

18. A smart electrical power meter with auto-switching control for optimizing energy saving in accordance with claim 1, wherein a processing unit to automatically control the power on/off according to the measured power, sensor signals, user input, schedules and control strategies;

19. A smart electrical power meter with auto-switching control for optimizing energy saving in accordance with claim 1, wherein storage units to save data, control strategies and algorithms.
